(19) United States
(12) Patent Application Publication
(10) Pub. No.: US 2009/0273046 A1
(43) Pub. Date: Nov. 5, 2009

(54) Process for Producing Solid-State Image Sensing Device, Solid-State Image Sensing Device and Camera

(76) Inventors: Yuichi Inaba, Osaka (JP); Masahiro Kasano, Osaka (JP)

Correspondence Address: MCDERMOTT WILL & EMERY LLP, 600 13TH STREET, NW, WASHINGTON, DC, 20005-3096, US

(21) Appl. No.: 11/887,732

(22) PCT Filed: May 10, 2006
(86) PCT No.: PCT/JP2006/309424

§ 371 Date: Oct. 3, 2007

(30) Foreign Application Priority Data
Jul. 6, 2005 (JP) 2005-197249

(51) Int. Cl. H01L 31/0232; H01L 21/18

(52) U.S. Cl. 257/432; 438/70; 257/E21.085; 257/E31.127

(57) ABSTRACT

In the formation of a multilayer interference filter that is included in a solid-state imaging device, at the outset, a titanium dioxide layer (401), a silicon dioxide layer (402), a titanium dioxide layer (403), and a spacer layer are successively laminated on an interlayer insulation film (304) to form a lower films. Next, the reflectance characteristics of the lower films are measured to specify the thickness of the lower films. When the thickness is deviated from the design value, the thickness of the spacer layer (404), and the thickness of upper films that include titanium dioxide layers (407, 409) and silicon dioxide layers (408, 410) are changed. Then, according to the changes, the spacer layer (404) is etched to regulate the thickness, and the upper films are formed thereon.

### TECHNICAL FIELD

The present invention relates to a solid-state imaging device, a method for manufacturing the same, and a camera, and more particularly to a technique for producing the solid-state imaging device at a higher yield rate.

### BACKGROUND ART

In recent years, solid-state imaging devices that have been widely prevalent are provided with color filters for color separation.

FIG. 9 is a cross-sectional diagram showing a pixel part of a solid-state imaging device of conventional technology. As shown in FIG. 9, a semiconductor imaging device 9 includes a semiconductor substrate 901 on which a gate insulation film 903, a transfer electrode 904, an interlayer insulation film 905, a light shielding film 906, an interlayer insulation layer 907, a planarization film 908, a convex part 909, and an on-chip color filter 910 are successively laminated.

Also, on the side of the interlayer insulation layer 907 of the semiconductor substrate 901, a light receiving area 902 is formed. The convex part 909 is made of a same material as the planarization film 908, and is convex lens-shaped. The on-chip color filter 910 is composed of a silicon dioxide (SiO₂) layer 910A and a titanium dioxide (TiO₂) layer 910B that are alternately laminated on each other.

With the above-described structure, color-filters for every pixel can be formed at once (Patent Document 1).

[Patent Document 1] Japanese laid-open Patent Application No. 2000-180621

### DISCLOSURE OF THE INVENTION

### The Problems the Invention is Going to Solve

However, the color separation function of the on-chip color filter 910 of conventional technology is determined by the number of layers of the silicon dioxide film 910A and the titanium dioxide film 910B, and the film thickness of each of the layers. In other words, in order to obtain the on-chip color filter 910 that has a desired color separation function, each of the layers that constitutes the on-chip color filter 910 needs to be formed accurately so as to have the required film thickness.

Specifically, in order to realize spectral characteristics as designed, all of the layers need to be formed such that errors in film thickness do not exceed 2%. Forming the on-chip color filter 910 with such a high accuracy is difficult, which results in a low yield rate. Accordingly, the manufacturing cost of the on-chip color filters 910 becomes high, which also affects cameras that have the on-chip color filters 910 therein.

In view of the above-described problems, the object of the present invention is to provide a solid-state imaging device, a method for manufacturing the same and a camera that can realize a desired optical characteristic at reduced cost.

### Means to Solve the Problems

In order to achieve the above-described object, the present invention provides a manufacturing method of a solid-state imaging device that filters incident light with use of a multilayer interference filter, the multilayer interference filter including a spacer layer sandwiched between a first λ/4 multilayer and a second λ/4 multilayer, the manufacturing method comprising the steps of: forming the first λ/4 multilayer; forming the spacer layer on the first λ/4 multilayer; specifying a film thickness by measuring a reflectance characteristic of a film that is composed of the first λ/4 multilayer and the spacer layer; and forming the second λ/4 multilayer in a manner that, if the specified film thickness is smaller than a designed value of the film that is composed of the first λ/4 multilayer and the spacer layer, a film thickness of the second λ/4 multilayer is formed to be larger than a designed value of the second λ/4 multilayer, and, if the specified film thickness is larger than the designed value of the film that is composed of the first λ/4 multilayer and the spacer layer, the film thickness of the second λ/4 multilayer is formed to be smaller than the designed value of the second λ/4 multilayer.

### EFFECTS OF THE INVENTION

If the film thickness of a λ/4 multilayer or spacer layer, both of which constitute a multilayer interference filter, deviates from the designed value, the transmission wavelength area is also deviated. However, according to the above-described structure, even if the film thickness of a first λ/4 multilayer or spacer layer deviates from the designed value, by adjusting the film thickness of a second λ/4 multilayer, the deviation of the transmission wavelength area can be solved.

Therefore, it is possible to achieve an excellent color separation function. Also, yield loss due to the deviation of the transmission wavelength area can be prevented, resulting in cost reduction.

Furthermore, the present invention provides a manufacturing method of a color solid-state imaging device that filters incident light with use of a multilayer interference filter, the multilayer interference filter including a spacer layer sandwiched between a first λ/4 multilayer and a second λ/4 multilayer, the manufacturing method comprising: a first step for, when forming the first λ/4 multilayer, forming a multilayer identical with the first λ/4 multilayer, in a reference area that is on a wafer excluding an area for forming the color solid-state imaging device; a second step for, when forming the spacer layer on the first λ/4 multilayer, forming a layer in the reference area, the layer being identical with the spacer layer; a third step for specifying a film thickness by measuring a reflectance characteristic of the reference area; and a fourth step for forming the second λ/4 multilayer in a manner that, if the specified film thickness is smaller than a designed value of the reference area, a film thickness of the second λ/4 multilayer is formed to be larger than a designed value of the second λ/4 multilayer, and, if the specified film thickness is larger than the designed value of the reference area, the film thickness of the second λ/4 multilayer is formed to be smaller than the designed value of the second λ/4 multilayer.

According to the stated structure, even if the area of each of the pixels that constitute a color solid-state imaging device is so small that the reflectance characteristics cannot be measured, the reflectance characteristics in the reference area can be measured, whereby the thickness of the lower films of the color solid-state imaging device can be estimated, and the thickness of the upper films can be changed.

In this case, if the manufacturing method of the solid-state imaging device of the present invention further comprises a fifth step for etching parts of the spacer layer formed on the first λ/4 multilayer, each of the parts corresponding to respective transmitting light colors, and the layer identical with the spacer layer in the reference area, wherein the third step is performed after the fifth step, and the reflectance characteristic of the reference area is measured for each film thickness of the parts of the spacer layer, a transmission wavelength area can be adjusted for each color area of the multilayer interference filter that constitutes the color solid-state imaging device.

Also, the present invention provides the manufacturing method of the solid-state imaging device further comprising: a sixth step for forming a multilayer identical with the second λ/4 multilayer in a reference area, wherein the sixth step is performed in parallel with the third step. In this way, monochromatic sensors can be formed in the reference area, thereby preventing the reference area from being wasted. As a result, cost can be reduced.

Also, the present invention provides a solid-state imaging device that filters incident light with use of a multilayer interference filter, wherein the multilayer interference filter includes a spacer layer sandwiched between a first λ/4 multilayer and a second λ/4 multilayer, and a film thickness of the first λ/4 multilayer and a film thickness of the second λ/4 multilayer are different from each other. This makes it possible to provide excellent optical characteristics with low cost.

Furthermore, the present invention provides a solid-state imaging device including a multilayer interference filter, and monochromatic image sensors that detect lights, of different wavelength bands, wherein the monochromatic image sensors include (i) a first monochromatic image sensor for receiving outside light, and (ii) monochromatic image sensors except the first monochromatic image sensor, the monochromatic image sensors being for receiving light that is reflected by at least one other of the monochromatic image sensors. With the stated structure, monochromatic image sensors that have been manufactured in parallel with the color solid-state imaging device as described above can be combined with color image sensors to constitute the color solid-state imaging device (three-chip type).

The present invention provides a camera including a solid-state imaging device that filters incident light with use of a multilayer interference filter, wherein the multilayer interference filter includes a spacer layer sandwiched between a first λ/4 multilayer and a second λ/4 multilayer, and a film thickness of the first λ/4 multilayer and a film thickness of the second λ/4 multilayer are different from each other. With the stated structure, an image having excellent color reproducibility can be captured at low cost.

Furthermore, the present invention provides a camera including a solid-state imaging device that has a multilayer interference filter, and monochromatic image sensors that detect lights of different wavelength bands, wherein the monochromatic image sensors include (i) a first monochromatic image sensor for receiving outside light, and (ii) monochromatic image sensors except the first monochromatic image sensor, the monochromatic image sensors being for receiving light that is reflected by at least one other of the monochromatic image sensors. With the stated structure, it is possible to manufacture a three-chip type camera without wasting monochromatic sensors, which have been manufactured in parallel with the color solid-state imaging device having excellent color reproducibility.

### BRIEF DESCRIPTION OF THE DRAWING

FIG. 1 is a block diagram showing the major functional components of a digital still camera of one embodiment of the present invention.

FIG. 2 is a diagram showing the general structure of the solid-state imaging device 102 of one embodiment of the present invention.

FIG. 3 is a cross-sectional diagram showing a pixel part of the solid-state imaging device 102 of one embodiment of the present invention.

FIGS. 4A to 4D are diagrams showing the process flow of manufacturing the multilayer interference filter 306 of one embodiment of the present invention.

FIG. 5 are graphs showing the relationship between the reflectance characteristics of the lower films and the spectral characteristics of the multilayer interference filter in which, FIG. 5A shows the relationship between the film thickness of the lower films and the reflectance characteristics, and FIG. 5B shows the relationship between the change in the film thickness of the lower films and the peak wavelength of the multilayer interference filter.

FIGS. 6A to 6B are graphs showing the reflectance characteristics of the multilayer interference filter.

FIG. 7 is a planar diagram showing the arrangement of chips on a wafer according to the first modification of the present invention.

FIG. 8 is a block diagram showing the main structure of the color solid-state imaging device including a combination of chips 701R, 701G, and 701B according to the first modification of the present invention.

FIG. 9 is a cross-sectional diagram showing a pixel part of the solid-state imaging device of conventional technology.

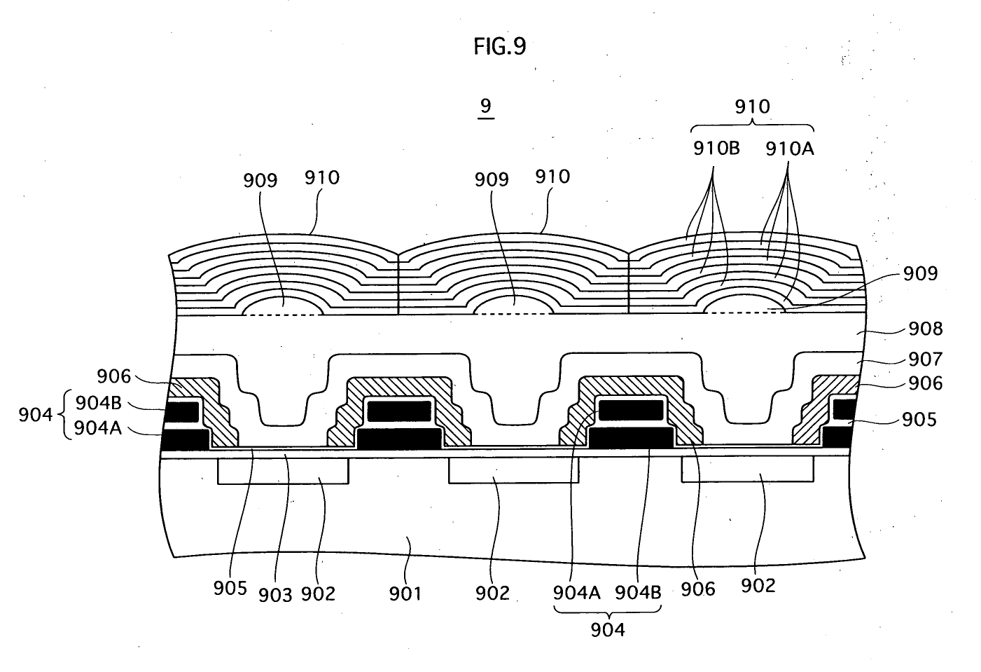

### DESCRIPTION OF CHARACTERS

1 digital still camera
7 wafer
101 lens
102 solid-state imaging device
103 color signal combining unit
104 image signal generating unit
105 device drive unit
201 unit pixel
202 vertical shift register
203 horizontal shift register
204 output amplifier
205 drive circuit
301 n-type semiconductor layer
302 p-type semiconductor layer
303 photodiode
304 interlayer insulation film
305 light shielding film
306 multilayer interference filter
307 condenser lens
401, 403, 407, 409 titanium dioxide layer
402, 408, 410 silicon dioxide layer
404 spacer layer
405, 406 resist film
501-507, 601-605 graph
701R, 701G, 701B, 702 chip

### BEST MODE FOR CARRYING OUT THE INVENTION

The following describes one embodiment of a solid-state imaging device, a method for manufacturing the same, and a camera according to the present invention, using a digital still camera as an example, with reference to the accompanying drawings.

[1] Structure of Digital Still Camera

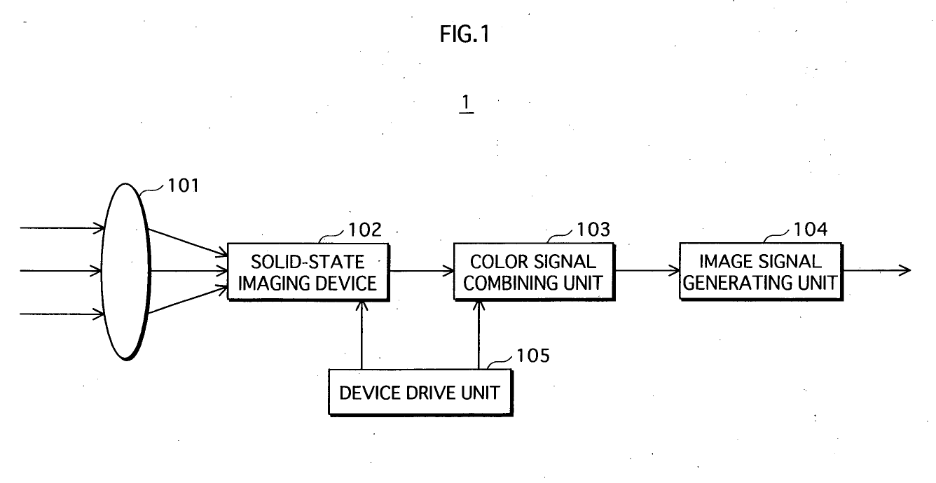

The following describes the structure of the digital still camera of the present embodiment. FIG. 1 is a block diagram showing the major functional components of a digital still camera of the present embodiment.

As shown in FIG. 1, a digital still camera 1 of the present embodiment includes a lens 101, a solid-state imaging device 102, a color signal combining unit 103, image signal generating unit 104, and a device drive unit 105.

The lens 101 focuses light that has entered the digital camera 1 into an imaging area of the solid-state imaging device 102. The solid-state imaging device 102 generates a color signal by converting incident light photoelectrically. The device drive unit 105 takes the color signal from the solid-state imaging device 102. The color signal combining unit 103 applies color shading to the color signal received from the solid-state imaging device 102. The image signal generating unit 104 generates a color image signal from the color signal that has been color shaded by the color signal combining unit 103. Finally, the color image signal is recorded onto a recording medium as color image data.

[2] Structure of Solid-State Imaging Device

The following describes the structure of the solid-state imaging device 102.

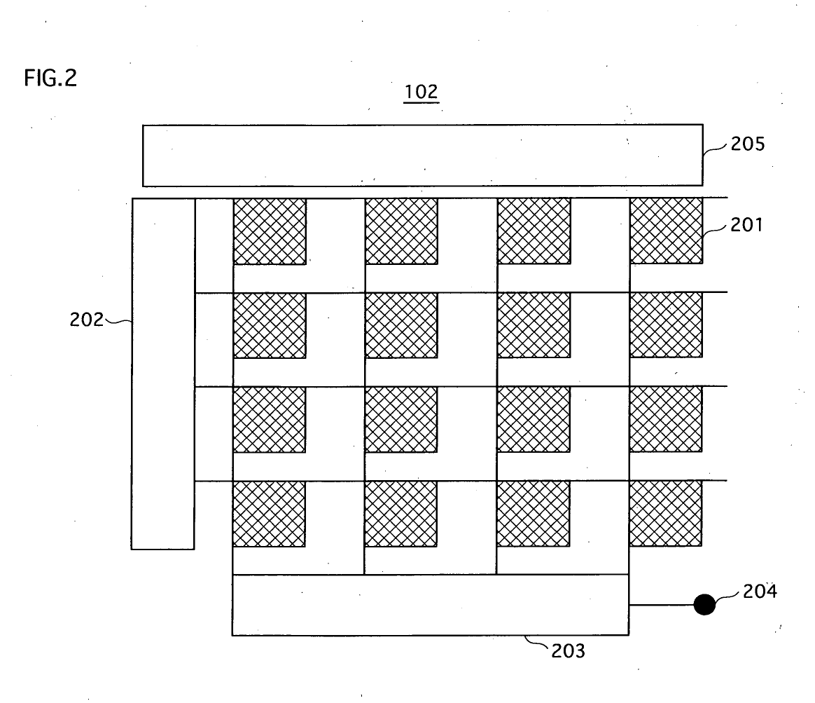

FIG. 2 shows the general structure of the solid-state imaging device 102. As shown in FIG. 2, the solid-state imaging device 102 selects each line of unit pixels 201 that are arranged two-dimensionally with use of a vertical shift register 202, and selects the line signals with use of a horizontal shift register 203, in order to output each color signal of the respective pixels from an output amplifier 204. Note that in the solid-state imaging device 102, a drive circuit 205 drives the vertical shift register 202, the horizontal shift register 203, and the output amplifier 204.

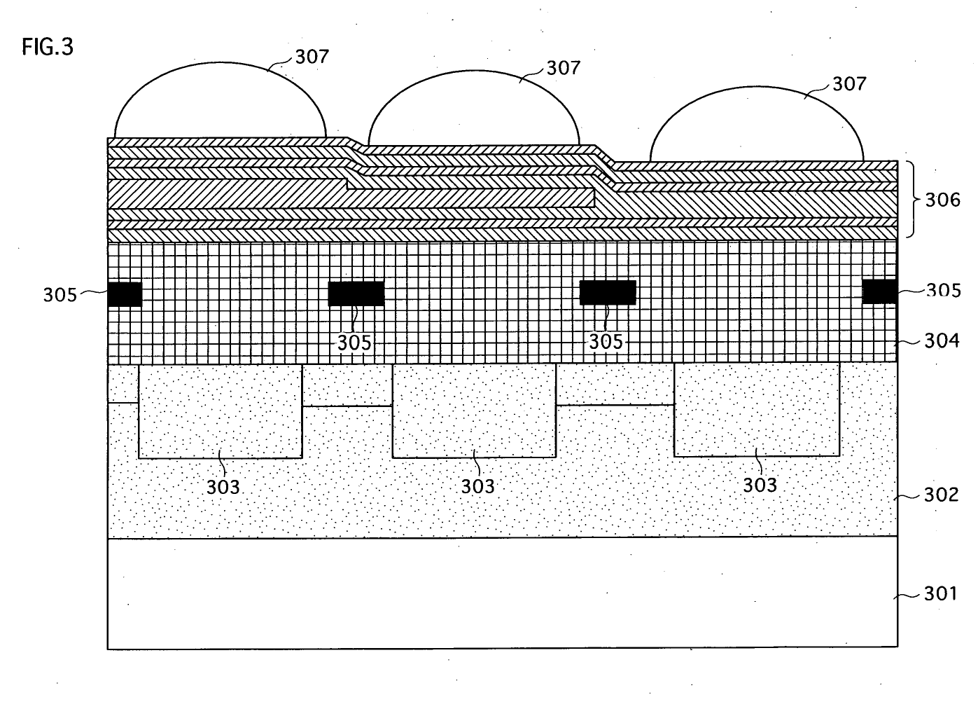

FIG. 3 is a cross-sectional diagram showing a pixel part of the solid-state imaging device 102. As shown in FIG. 3, the solid-state imaging device 102 includes an n-type semiconductor layer 301 on which a p-type semiconductor layer 302, an interlayer insulation film 304, a multilayer interference filter 306, and a condenser lens 307 are successively laminated.

On the side of the interlayer insulation film 304 in the p-type semiconductor layer 302, a photodiode 303 that has been formed by ion-implantation of an n-type impurity is disposed in each pixel. Each of the photodiodes 303 corresponds to a respective one of the condenser lenses 307. Also, between the photodiodes 303 that are adjacent to each other, a p-type semiconductor layer is interposed. This area is referred to as “device isolation area”.

In the interlayer insulation film 304, a light shielding film 305 is formed. The light shielding film 305 prevents light which has transmitted through the condenser lens 307 from entering the irrelevant photodiodes 303.

The multilayer interference filter 306 has a structure in which a spacer layer is sandwiched between two λ/4 multilayers. Each of the λ/4 multilayers is a four layered film that is composed of two types of dielectric layers, which have the same optical film thickness but a different refractive index, being alternately laminated on each other. Note that the optical film thickness is an index obtained by a physical film thickness being multiplied by a refractive index.

Generally, the λ/4 multilayer reflects light in a band (reflection band) centered on wavelength λ that is equivalent to four times the optical film thickness of a dielectric layer. However, the multilayer interference filter 306 transmits light whose wavelength is determined according to the film thickness of the spacer layer. Therefore, the film thickness is different for each of the light colors that are to be received by respective pixels facing the multilayer interference filter 306. The film thickness of red, green and blue areas are 516 nm, 481 nm, and 615 nm respectively.

[3] Manufacturing Method of Multilayer Interference Filter 306

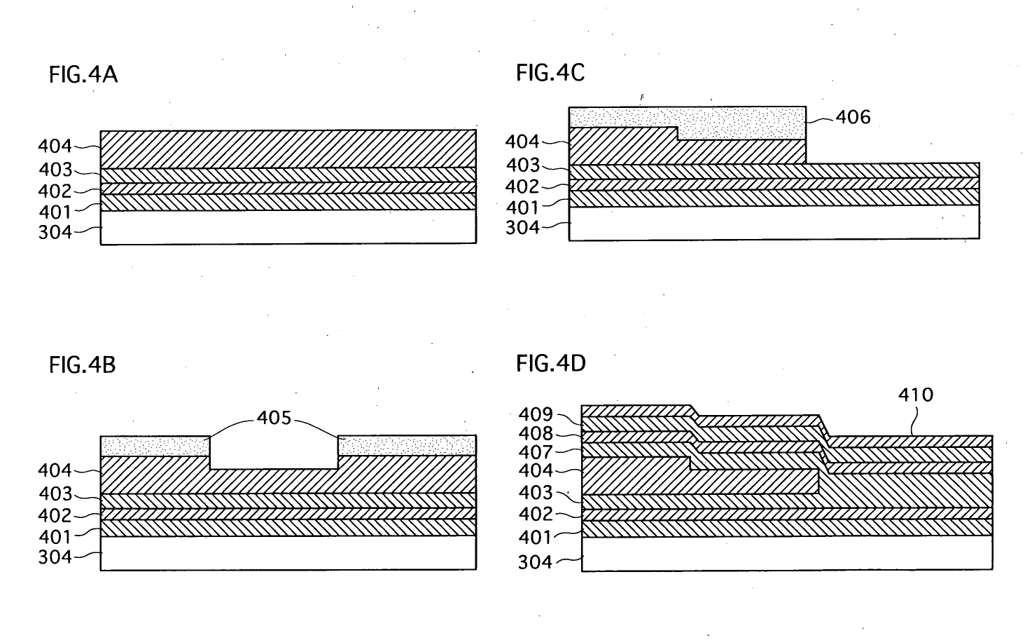

The following describes the method for manufacturing the multilayer interference filter 306. FIGS. 4A to 4D are diagrams showing the process flow of manufacturing the multilayer interference filter 306. In FIGS. 4A to 4D, the manufacturing process of the multilayer interference filter 306 proceeds from 4A to 4D. Also, figures of the n-type semiconductor layer 301, the p-type semiconductor layer 302, the photodiode 303 and the light shielding film 305 are omitted here.

First, with use of a high-frequency (RF: Radio Frequency) sputtering device, a titanium dioxide layer 401, a silicon dioxide layer 402, and a titanium dioxide layer 403 are successively laminated on the interlayer insulation film 304 in order to form the λ/4 multilayer. Furthermore, on top of the titanium dioxide layer 403, a spacer layer 404 is formed. The spacer layer is made of silicon dioxide.

Here, the reflectance characteristics of a laminated film (referred to as “lower films” hereinafter), which is composed of four layers including the titanium dioxide layers 401 and 403, the silicon dioxide layer 402, and the spacer layer 404 is measured. The reflectance characteristics are measured by wavelength spectrophotometry with use of white light. In the case that the reflectance characteristics show the occurrence of a manufacturing error in the film, thickness of the lower films, the thickness of the spacer layer 404, below-described titanium dioxide layers 407 and 409, and silicon dioxide layers 408 and 410 are adjusted in accordance with the error.

Next, the thickness of the spacer layer 404 is adjusted so that the multilayer interference filter 306 can transmit light colors that are each to be received by a corresponding one of the pixels.

In other words, after a resist film 405 is formed on the spacer layer 404, only the part of the resist film 405 corresponding to the area of the spacer layer 404 in which red light is to be transmitted (referred to as “red region” hereinafter) is removed. Then, with the resist film 405 being used as an etching mask, the red region of the spacer layer 404 is etched (FIG. 4B).

After the resist film 405 has been removed, a resist film 406 is formed on the spacer film 404. Then, only the part of the resist film 406 corresponding to the area of the spacer layer 404 in which green light is to be transmitted (referred to as “green region” hereinafter) is removed. Then, with the resist film 406 being used as an etching mask, the green region of the spacer layer 404 is etched (FIG. 4C).

In the case that the spacer layer 404 is etched, a resist agent may be applied on the whole surface of a wafer. After a pre-exposure bake (pre-bake), exposure may be performed with a photolithography device such as a stepper. Then, resist development and a final bake (post-bake) are performed to form a resist film, and finally an etching gas of tetrafluoromethane (CF4) type may be used.

After the resist film 406 is removed, on the spacer layer 404, and on the titanium dioxide layer 403 of the green region, a titanium dioxide layer 407, a silicon dioxide layer 408, a titanium dioxide layer 409, and a silicon dioxide layer 410 are successively laminated, whereby the λ/4 multilayer is formed to complete the multilayer interference filter 306.

[4] Reflectance Characteristics of Lower Films and Spectral Characteristics of Multilayer Interference Filter

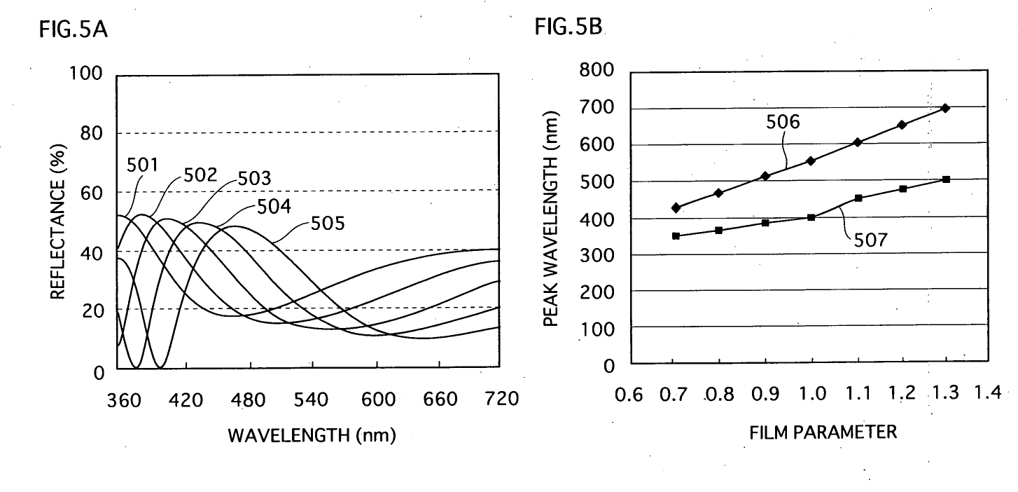

The following describes the relationship between the reflectance characteristics of the lower films and the spectral characteristics of the multilayer interference filter. FIG. 5 are graphs showing the relationship between the reflectance characteristics of the lower films and the spectral characteristics of the multilayer interference filter in which, FIG. 5A shows the relationship between the film thickness of the lower films and the reflectance characteristics, and FIG. 5B shows the relationship between the changes in the film thickness of the lower films and the peak wavelength of the multilayer interference filter.

In FIG. 5A, the graphs 501-505 each show the reflectance characteristics in the case that the film thickness of the lower films deviates from a designed value by −20%, −10%, 0%, 10%, and 20%. Also, the vertical axis represents the reflectance, and the horizontal axis represents the wavelength.

Here, in each of the graphs, the point at which the reflectance is the highest is referred to as a convex peak, and, within a range in which the wavelength is 420 nm or more, the point at which the reflectance is the lowest is referred to as a concave peak. As seen in FIG. 5A, the greater the film thickness of the lower films is, the more the convex peak wavelength and the concave peak wavelength both shift to the longer wavelength side.

In FIG. 5B, the graphs 506 and 507 show the relationship between the convex peak wavelength and the film thickness of the lower films, and the relationship between the concave peak wavelength and the film thickness of the lower films respectively. The vertical axis represents the peak wavelength, and the horizontal axis represents the ratio of the film thickness of the lower films with respect to the design value (referred to as “film parameter” hereinafter). As shown in FIG. 5B, the convex peak wavelength 506 and the concave peak wavelength 507 both increase linearly in proportion to the film parameter. Therefore, if the reflectance characteristics of the lower films are measured to specify the convex peak wavelength and the concave peak wavelength, a deviation of the film thickness of the lower films from a designed value can be measured accurately.

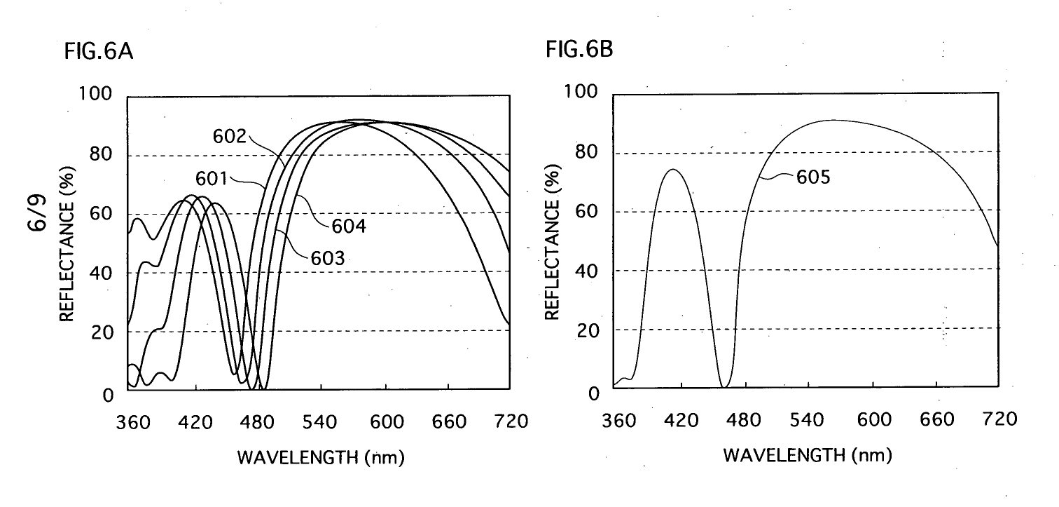

FIGS. 6A to 6B are graphs showing the reflectance characteristics of the multilayer interference filter.

FIG. 6A is a graph showing the reflectance characteristics that can be obtained by, when the film thickness of the lower films is 10% larger than a designed value, changing the thickness of the λ/4 multilayer (referred to as “upper films” hereinafter) that is composed of a titanium dioxide layer 407, a silicon dioxide layer 408, a titanium dioxide layer 409, and a silicon dioxide layer 410.

In FIG. 6A, the graphs 601-604 each show the reflectance characteristics in the case that the thickness of the upper films is changed from a designed value by −20% (decreased), −10% (decreased), 0% (as designed), and 10% (increased). As shown in FIG. 6A, by changing the thickness of the upper films, it is possible to change the reflectance characteristics of the multilayer interference filter.

In FIG. 6B, the graph 605 shows the reflectance characteristics of when the thickness of the lower films is the same as the design value. When FIG. 6B is compared to FIG. 6A, the graph 602 is the most similar to the graph 605. Therefore, if the film thickness of the lower films is 10% larger than the designed value, the film thickness of the upper films can be reduced by 10%, so that the desired reflectance characteristics of the multilayer interference filter can be realized as a whole.

Generally, even though the thickness of the lower films deviates from a designed value, if the reflectance characteristics of the lower films are measured to specify the magnitude of the deviance, and the thickness of the upper films is adjusted depending on the magnitude of the deviance, the optical characteristics of the multilayer interference filter can be adjusted.

[5] Modifications

While the present invention has been described in accordance with the specific embodiments outlined above, it is evident that the present invention is not limited to such. The following cases are also included in the present invention.

(1) Although it is not particularly referred to in the above-described embodiment, in a semiconductor process for forming the multilayer interference filter, since the reflectance characteristics need to be measured as described above, each of the pixels in one-chip preferably includes the multilayer interference filter that transmits the same color of light in the chip.

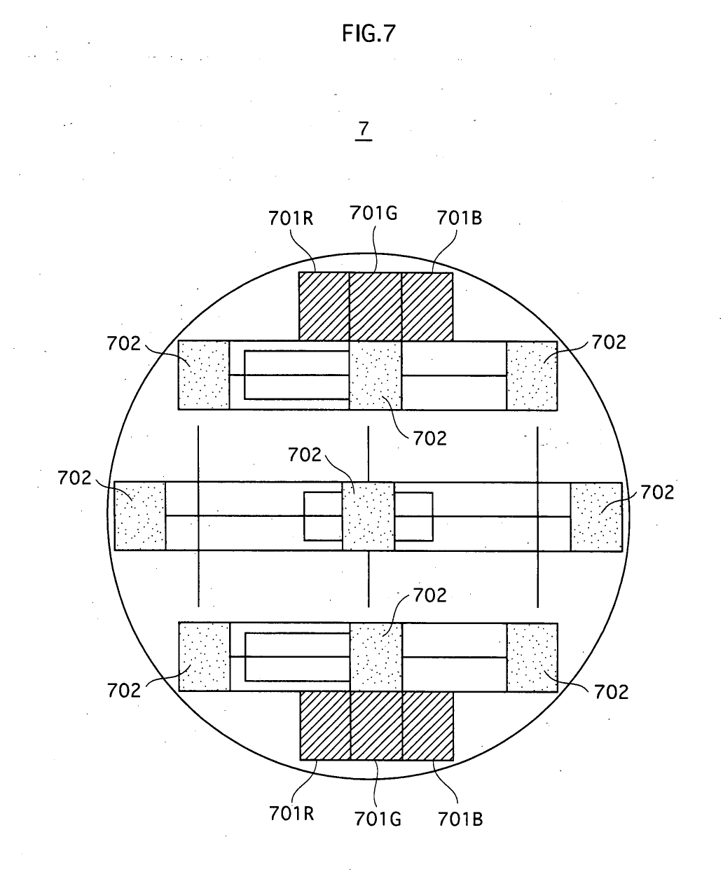

FIG. 7 is a planar diagram showing the arrangement of chips on a wafer according to the present modification. As shown in FIG. 7, on the wafer 7, two kinds of chips, namely, chips 701R, 701G and 701B, and, a chip 702 are formed. The chips 701R, 701G, and 701B are monochromatic sensors, and each of the pixels in one-chip includes a respective one of multilayer interference filters that transmit the same color of light in the chip.

Also, the chip 702 is a color image sensor, and each of the pixels in one-chip includes a respective one of multilayer interference filters that transmit light of one of the three primary colors. The chip 701R detects red light among three primary color lights that are detected by the chip 702. Also, the chip 701G and 701B detect green light and blue light respectively.

With the stated structure, after the film thicknesses of the spacer layers of the chips 701R, 701G, and 701B are adjusted by etching or the like, the reflectance characteristics of the chips are measured, whereby not only the film thickness of the chips 701R, 701G, and 701B, but also the film thickness of the chip 702 can be specified. Also, the film thickness of the upper films can be adjusted. As a result, all the multilayer interference filters, can be formed with sufficient accuracy, and the yield rates of the chips 701R, 701G, and 701B, and the chip 702 can be improved.

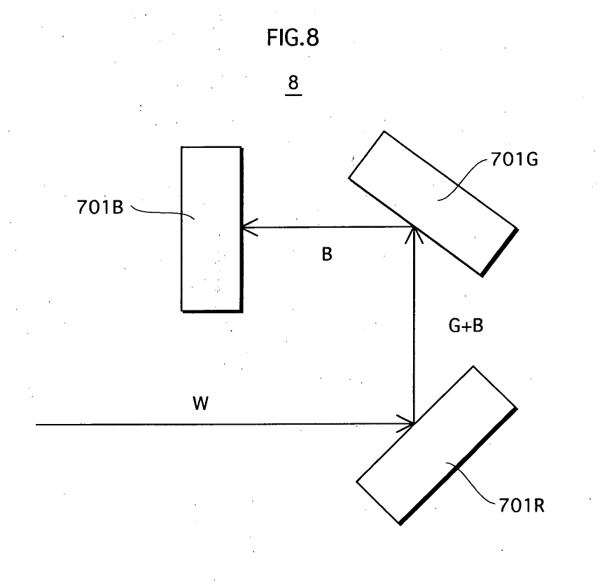

Note that the chips 701R, 701G, and 701B, which are monochromatic image sensors, can be combined to make a color solid-state imaging device. FIG. 8 is a block diagram showing the main structure of the color solid-state imaging device including a combination of the chips 701R, 701G, and 701B. In FIG. 8, a color solid-state imaging device 8 first receives white light W that includes all the elements of the three primary colors from the chip 701R.

The multilayer interference filter of the chip 701R transmits only the red light, and reflects lights of other colors. Therefore, the chip 701R detects a red element from the white light W. Then, a green element G and a blue element B are reflected, and directed to the chip 701G.

The multilayer interference filter of the chip 701G transmits only the green light, and reflects the blue light. Therefore, the chip 701G detects the green element G from the white light W, and the blue light B is directed to the chip 701B. The chip 701B detects the blue element B of the white light W.

Consequently, the color solid-state imaging device 8 can detect each of the three primary colors included in the white light W, with use of the chips 701R, 701G, and 701B.

### INDUSTRIAL APPLICABILITY

A solid-state imaging device, a method for manufacturing the same, and a camera according to the present invention are useful as a solid-state imaging device and a camera that can capture an image which reproduces colors with excellent accuracy, and as a method for manufacturing the same.

1. A manufacturing method of a solid-state imaging device that filters incident light with use of a multilayer interference filter, the multilayer interference filter including a spacer layer sandwiched between a first λ/4 multilayer and a second λ/4 multilayer, the manufacturing method comprising the steps of:
forming the first λ/4 multilayer;
forming the spacer layer on the first λ/4 multilayer;
specifying a film thickness by measuring a reflectance characteristic of a film that is composed of the first λ/4 multilayer and the spacer layer; and
forming the second λ/4 multilayer in a manner that, if the specified film thickness is smaller than a designed value of the film that is composed of the first λ/4 multilayer and the spacer layer, a film thickness of the second λ/4 multilayer is formed to be larger than a designed value of the second λ/4 multilayer, and, if the specified film thickness is larger than the designed value of the film that is composed of the first λ/4 multilayer and the spacer layer, the film thickness of the second λ/4 multilayer is formed to be smaller than the designed value of the second λ/4 multilayer.

2. A manufacturing method of a color solid-state imaging device that filters incident light with use of a multilayer interference filter, the multilayer interference filter including a spacer layer sandwiched between a first λ/4 multilayer and a second λ/4 multilayer, the manufacturing method comprising:
a first step for, when forming the first λ/4 multilayer, forming a multilayer identical with the first λ/4 multilayer, in a reference area that is on a wafer excluding an area for forming the color solid-state imaging device;
a second step for, when forming the spacer layer on the first λ/4 multilayer, forming a layer in the reference area, the layer being identical with the spacer layer;
a third step for specifying a film thickness by measuring a reflectance characteristic of the reference area; and
a fourth step for forming the second λ/4 multilayer in a manner that, if the specified film thickness is smaller than a designed value of the reference area, a film thickness of the second λ/4 multilayer is formed to be larger than a designed value of the second λ/4 multilayer, and, if the specified film thickness is larger than the designed value of the reference area, the film thickness of the second λ/4 multilayer is formed to be smaller than the designed value of the second λ/4 multilayer.

3. The manufacturing method of the solid-state imaging device of claim 2 further comprising:
a fifth step for etching parts of the spacer layer formed on the first λ/4 multilayer, each of the parts corresponding to respective transmitting light colors, and the layer identical with the spacer layer in the reference area, wherein
the third step is performed after the fifth step, and the reflectance characteristic of the reference area is measured for each film thickness of the parts of the spacer layer.

4. The manufacturing method of the solid-state imaging device of claim 2 further comprising:
a sixth step for forming a multilayer identical with the second λ/4 multilayer in a reference area, wherein
the sixth step is performed in parallel with the third step.

5. A solid-state imaging device that filters incident light with use of a multilayer interference filter, wherein
the multilayer interference filter includes a spacer layer sandwiched between a first λ/4 multilayer and a second λ/4 multilayer, and
a film thickness of the first λ/4 multilayer and a film thickness of the second λ/4 multilayer are different from each other.

6. A solid-state imaging device including a multilayer interference filter, and monochromatic image sensors that detect lights of different wavelength bands, wherein
the monochromatic image sensors include (i) a first monochromatic image sensor for receiving outside light, and (ii) monochromatic image sensors except the first monochromatic image sensor, the monochromatic image sensors being for receiving light that is reflected by at least one other of the monochromatic image sensors.

7. A camera including a solid-state imaging device that filters incident light with use of a multilayer interference filter, wherein
the multilayer interference filter includes a spacer layer sandwiched between a first λ/4 multilayer and a second λ/4 multilayer, and
a film thickness of the first λ/4 multilayer and a film thickness of the second λ/4 multilayer are different from each other.

8. A camera including a solid-state imaging device that has a multilayer interference filter, and monochromatic image sensors that detect lights of different wavelength bands, wherein
the monochromatic image sensors include (i) a first monochromatic image sensor for receiving outside light, and (ii) monochromatic image sensors except the first monochromatic image sensor, the monochromatic image sensors being for receiving light that is reflected by at least one other of the monochromatic image sensors.
